(19) United States
(12) Patent Application Publication
(10) Pub. No.: US 2012/0255607 A1
(43) Pub. Date: Oct. 11, 2012

(54) SEMICONDUCTOR COATED MICROPOROUS GRAPHENE SCAFFOLDS

(75) Inventors: Joseph Roy-Mayhew, Princeton, NJ (US); Ilhan Aksay, Princeton, NJ (US)

(73) Assignee: The Trustees of Princeton University, Princeton, NJ (US)

(21) Appl. No.: 13/510,678

(22) PCT Filed: Nov. 18, 2010
(86) PCT No.: PCT/US10/57201

§ 371 Date: Jun. 14, 2012

Related U.S. Application Data
(60) Provisional application No. 61/262,319, filed on Nov. 18, 2009.

(51) Int. Cl. H01L 31/0224; B32B 7/02; H01L 21/20; B32B 9/04; B32B 5/00; B82Y 40/00; B82Y 30/00

(52) U.S. Cl. 136/256; 428/408; 428/212; 428/220; 438/478; 977/734; 977/948; 257/E21.09; 977/842

(57) ABSTRACT

A high surface area scaffold to be used for a solar cell, made of a three-dimensional percolated network of functionalized graphene sheets. It may be used in the preparation of a high surface area electrode by coating with a semi conductive material. Electronic devices can be made therefrom, including solar cells such as dye-sensitized solar cells.

### REFERENCE TO RELATED APPLICATIONS

The present application claims priority to U.S. Provisional Application No. 61/262,319, filed Nov. 18, 2009, the entire contents of which are hereby incorporated by reference. The present application is related to U.S. Provisional Application No. 61/391,670, filed Oct. 10, 2010, the entire contents of which are hereby incorporated by reference.

### BACKGROUND OF THE INVENTION

1. Field of the Invention

The present invention relates to high surface area scaffolds to be used use as electrodes, in particularly solar cells such as dye-sensitized solar cells.

2. Description of the Related Art

Generally speaking, photovoltaic systems are implemented to convert light energy into electricity for a variety of applications. Power production by photovoltaic systems may offer a number of advantages over conventional systems. These advantages may include, but are not limited to, low operating costs, high reliability, modularity, low construction costs, and environmental benefits. As can be appreciated, photovoltaic systems are commonly known as “solar cells,” so named for their ability to produce electricity from sunlight.

Conventional solar cells convert light into electricity by exploiting the photovoltaic effect that exists at semiconductor junctions. Accordingly, conventional semiconductor layers generally absorb incoming light to produce excited electrons. In addition to the semiconductor layers, solar cells generally include a cover or other encapsulant, seals on the edges of the solar cell, a front contact electrode to allow the electrons to enter a circuit, and a back contact electrode to allow the electrons to complete the circuit.

One particular type of solar cell is a dye-sensitized solar cell. A dye-sensitized solar cell generally uses an organic dye to absorb incoming light to produce excited electrons. The dye-sensitized solar cell generally includes two planar conducting electrodes arranged in a sandwich configuration. A dye-coated semiconductor film separates the two electrodes which may comprise glass coated with a transparent conducting oxide (TCO) film, for example. The semiconductor layer is porous and has a high surface area thereby allowing sufficient dye for efficient light absorption to be attached as a molecular monolayer on its surface. The remaining intervening space between the electrodes and the pores in the semiconductor film (which acts as a sponge) is filled with an organic electrolyte solution containing an oxidation/reduction couple such as triiodide/iodide, for example.

One exemplary technique for fabricating a dye-sensitized solar cell is to coat a conductive glass plate with a semiconductor film such as titanium dioxide (TiO₂) or zinc oxide (ZnO), for example. The semiconductor film is saturated with a dye and a single layer of dye molecules self-assembles on each of the particles in the semiconductor film, thereby “sensitizing” the film. A liquid electrolyte solution containing triiodide/iodide is introduced into the semiconductor film. The electrolyte fills the pores and openings left in the dye-sensitized semiconductor film. To complete the solar cell, a second planar electrode with low overpotential for triiodide reduction is implemented to provide a cell structure having a dye-sensitized semiconductor and electrolyte composite sandwiched between two counter-electrodes.

Conventional dye-sensitized solar cells may be fabricated using planar layered structures, as set forth above. The absorption of light by the dye excites electrons in the dye which are injected into the semiconductor film, leaving behind an oxidized dye cation. The excited electrons diffuse through the semiconductor film by a “random walk” through the adjacent crystals of the film towards an electrode. During the random walk of the electron to the electrode, the electron may travel a significant distance, and the electron may be lost by combining with a component of the electrolyte solution or with defects in the semiconductor, also known as “recombination.” Under irradiation by sunlight, the density of electrons in the semiconductor may be high such that such electron losses significantly reduce the maximum voltage and therefore the efficiency achievable by the solar cells. It may be advantageous to reduce the likelihood of recombination by reducing the travel path of the electron through the semiconductor and thereby reducing the length of time it takes for the electron to diffuse through the semiconductor to the conductive oxide of the electrode. One technique for reducing the travel distance of the electron is to reduce the thickness of the semiconductor film and thus, the distance the electron has to travel to reach an electrode. Disadvantageously, reduction in the thickness of the semiconductor film may reduce the light absorption in the dye, thereby reducing the efficiency of the solar cell.

Also, the injection of the electron from the dye into the semiconductor material leaves behind an oxidized dye cation. The oxidized dye is reduced by transfer of an electron from an iodide ion, leading to the production of triiodide that diffuse through the electrolyte solution to the back electrode where a catalyst supplies the missing electron thereby closing the circuit. The back electrode generally is coated with particles of carbon or platinum to catalyze the electron transfer to the triiodide. The electrolyte solution is typically made in an organic solvent. Generally speaking, less volatile solvents, including ionic liquids, with a high boiling point are more viscous and impede the diffusion of ions to the point where the diffusion limits the power output and hence the efficiency of the solar cell. Such solvents may be advantageous in providing cell longevity, especially for cells fabricated on a polymer substrate, because polymer substrates may allow less viscous solvents having a low boiling point to diffuse out of the solar cell over time. Because the triiodide ion may originate from anywhere in the part of the electrolyte solution in contact with the dyed surface of the semiconductor, the ion may have to travel a long torturous path through the labyrinth created by the random pore structure of the semiconductor from near the front electrode to the back electrode to complete the circuit. These long paths may limit the diffusion current in the solar cell. Decreasing the travel distance of the ions may advantageously reduce the limitations caused by the slow diffusion of the ions. However, as previously described, reducing the thickness of the semiconductor film to reduce the ion transport path may disadvantageously reduce the light absorption of the dye.

Skotheim, U.S. Pat. No. 4,190,950 discloses an early dye-sensitized solar cell with a greatly improved cell power conversion efficiency using microporous TiO₂ and a ruthenium-based dye disclosed by Gratzel, U.S. Pat. No. 4,927,721. Gruner, U.S. Published Application 2007/0284557 discloses the use of graphene films as a transparent conductor for use in solar cells as flat sheets, not porous networks. Low temperature TiO₂ coating techniques have been around for over 30 years [see, e.g., Kholschutter, U.S. Pat. No. 3,553,001] and even recently have been applied to graphene. However, they have not been used in a dye-TiO₂-graphene network system for dye-sensitized solar cells. Sager, U.S. Pat. No. 6,852,920, discloses a bulk heterogeneous solar cell using a carbonaceous material, yet the carbonaceous material in the bulk heterogeneous cells is used for its electron affinity to create an electric field and separate charge, not primarily as a conductive material in the cells.

The limitations of very short electron diffusion length (10 nm) in the bulk heterogeneous cell are not applicable in the dye-sensitized solar cell which works through electron injection into a semiconductor. Other patents try to solve the same underlying problem of getting electrons out of the cell, but in different ways. For instance, Spivack et al., U.S. Pat. No. 7,145,071, discloses a finger electrode for dye-sensitized solar cells, using a macroscopic porous electrode. Wakayama, U.S. Pat. No. 6,194,650 disclose making coatings of microporous structures using supercritical fluids. In this patent, activated carbon was proposed as a middle electrode of a dye-sensitized solar cell. However, activated carbon does not form a percolated network, nor can it be transparent.

FIG. 1 illustrates a conventional dye-sensitized solar cell. As can be appreciated, the electrodes of the solar cell are planar structures. The solar cell may be fabricated by implementing any one of a number of techniques and using a variety of materials, as can be appreciated by those skilled in the art. In one embodiment, a layer of semiconductor material, such as a layer of nanocrystalline TiO₂ 2 may be deposited on a transparent conducting substrate 1, such as a transparent conductive layer on a glass substrate. The TCO coated transparent substrate 1 forms the front electrode of the solar cell. As can be appreciated, the substrate 1 may comprise other transparent materials such as plastic. The TiO₂ layer 2 may be deposited at a thickness in the range of 5-20 microns, for example. The TiO₂ layer 2 is generally disposed at a thickness of at least 10 microns to facilitate efficient light absorption, as explained further below. The TiO₂ layer 2 of the exemplary solar cell has a thickness of approximately 10 microns, as illustrated in FIG. 1. The TiO₂ layer 2 may be sintered or dried and pressed or chemically modified to provide mechanical strength, electrical conductivity and adherence to the substrate.

A back electrode 6 may be positioned on top of the TiO₂ layer 2. The back electrode 6 may be coated with a TCO layer covered with catalytic particles 5 such as platinum or carbon. The back electrode 6 may be positioned such that a small space (one micron, for example) is provided between the TiO₂ layer 2 and the back electrode 6. Accordingly, minimal contact points (or no contact points, as in the present embodiment) may exist between the TiO₂ layer 2 and the back electrode 6. A seal 7, such as an organic material or glass for instance, is provided to seal the edges of the solar cell. As can be appreciated, while the height of the solar cell may be in the range of 5-20 microns, the lateral dimension of the solar cell (i.e. between each of the seals 7) may be in the range of 0.5-10 centimeters, for instance. The lateral dimension of the exemplary solar cell is illustrated as having an exemplary range of approximately 1-10 centimeters, for example.

The back electrode 6 may include filling holes (not shown) through which a solution of dye suitable for sensitizing the TiO₂ layer 2 can be injected. As can be appreciated by those skilled in the art, the dye 3 used to saturate and sensitize the TiO₂ layer 2 may include group VIII metal complexes of bipyridine carboxylic acids, such as Ru(4,4′-dicarboxy-2,2′-bipyridyl)₂(SCN)₂, for instance. Once the TiO₂ layer 2 is saturated, the dye-coated TiO₂ layer 2,3 may be rinsed and cleaned, as can be appreciated by those skilled in the art. An electrolyte layer 4 is injected through the filling holes in the back electrode 6 to fill the pores in the semiconductor film and the remaining space between the glass substrate 1 and the back electrode 6. The electrolyte layer 4 facilitates the movement of ions formed by a separation of electrons in the dye-sensitized TiO₂ layer 2 upon exposure by an incident light source (not shown), such as sunlight, as explained further below. Finally, the filling holes may be sealed and electrical contact is made between the glass substrate 4 and the back electrode 6.

As illustrated with respect to FIG. 1, the light path through the sensitized TiO₂ layer 2 is approximately 10 microns. When an incident light source is directed through the glass substrate 1 or back electrode 6, the incident light excites electrons within the dye 3, and the electrons are transferred into the TiO₂ layer 2. The electrons diffuse through the adjacent crystals in the TiO₂ layer 2 through a “random walk.” While the maximum distance of any of the particles in the TiO₂ layer 2 is approximately 10 microns from the glass substrate 1, the distance an electron may travel through the TiO₂ layer 2 to reach the glass substrate 1 may be significantly greater than 10 microns as the electron randomly diffuses through adjacent nanocrystals in the TiO₂ layer 2. During the random walk of the electron to the glass substrate 1, the electron may be lost by combining with a component of the electrolyte layer 4 or defects in the semiconductor 2. In general, the longer it takes for an electron to diffuse through the TiO₂ layer 2 to the underlying TCO coated substrate 1, the more likely that the electron will disadvantageously recombine. Under irradiation by sunlight the density of the electrons in the TiO₂ layer 2 may be high enough that the losses significantly reduce the maximum voltage and therefore the efficiency achievable by the solar cell. As previously discussed, reducing the thickness of the TiO₂ layer 2 to reduce the likelihood of electron recombination during the random walk by decreasing the migration path of the electrons is disadvantageous, because reducing the thickness of the TiO₂ layer 2 reduces the light absorption potential of the TiO₂ layer 2.

Further, ions formed by reaction of components of the electrolyte 4 with dye molecules 3 which have injected excited electrons into the semiconductor diffuse to the back electrode 6 through the electrolyte 4 to complete the circuit. Because the TiO₂ layer 2 is “porous” and therefore comprises a continuous system of pores, ions in the electrolyte 4 can diffuse through the TiO₂ layer 2. In the present exemplary embodiment, the maximum distance from any ion to the back electrode 6 is the thickness of the TiO₂ layer 2 plus the additional space between the TiO₂ layer 2 and the back electrode 6. In the present exemplary embodiment, the maximum distance from any ion to the back electrode is approximately 11 microns, though an ion may travel a longer distance due to the random path it diffuses. As previously described, the electrolyte layer 4 is typically an organic solvent. While polar, stable and non-viscous solvents are desirable, the solvents implemented in the solar cell such as acetonitrile, are generally volatile. Generally speaking, less volatile solvents are more viscous and impede the diffusion of ions to the point where the diffusion limits the power output and therefore the efficiency of the solar cell. In solar cells implementing a plastic substrate 1, the loss of volatile solvents may create even more of a problem.

In summary, the solar cell of FIG. 1 includes a TiO₂ layer 2 coated with dye 3 and deposited at a thickness of about 10 microns onto a TCO coated planar substrate 1. A TCO coated glass 6 with catalytic particles 5 provides the back electrode. The TiO₂ layer 2 is in direct contact with the conductive glass substrate 1 to provide an electrical connection for the excited electrons. The contact area between the TiO₂ layer 2 and the back electrode layer 6 is minimized and in the present exemplary embodiment, does not exist (i.e. the TiO₂ layer 2 is isolated from the back electrode layer 6). The shortest light path through the TiO₂ layer 2 is 10 microns. Although longer light paths may be desirable to provide more light absorption, the losses due to increased recombination and from ion diffusion limitations cause thicker layers TiO₂ 2 to reduce the solar cell efficiency.

### SUMMARY OF THE INVENTION

Accordingly, one object of the present invention is to provide a high surface area, scaffold for use in production of solar cells.

Another object of the present invention is to provide a charge selective electrode having high surface area formed from the scaffold of the present invention, that increases efficiency of solar cells and electronics in which it is used.

A further object of the present invention is to provide a solar cell using the charge selective electrode of the present invention.

A still further object of the present invention is to provide a dye-sensitized solar cell containing the charge selective electrode of the present invention, having improved efficiency and being more easily produced.

These and other objects of the present invention, either individually or in combinations thereof, have been satisfied by the discovery of a high surface area conductive scaffold to be used for a semiconductor, comprising:

a three dimensional percolated network of functionalized graphene sheets.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 provides an illustration of a conventional dye-sensitized solar cell structure.

FIG. 2 provides a graphical depiction of an embodiment of the layered architecture of a high surface area semiconducting scaffold of the present invention.

FIG. 3 provides scanning electron microscope (SEM) images of FGS tapes created and coated with TiO₂ in accordance with the present invention.

FIG. 4 provides an X-ray diffraction spectrum of titania coated FGS Tape according to the present invention.

FIG. 5 provides a graph showing J-V and Power-V curves obtained from an embodiment of dye-sensitized solar cell in accordance with the present invention.

### DETAILED DESCRIPTION OF THE PREFERRED EMBODIMENTS

The present invention relates to a three-dimensional, percolated network of functionalized graphene sheets as a high surface area scaffold for solar cells. The scaffold may be conductive. In a preferred embodiment, the resulting shell-core electrode can be incorporated into dye-sensitized solar cells through solution processable means to reduce electron recombination and improve device efficiency.

The present invention provides electrodes having high available surface area comprising a three-dimensional percolated network of graphene, preferably from stacks of 1 to 10 graphene sheets, more preferably single sheet graphene, which comprise a layer between 0.1 and 100 microns thick, and is preferably semi-transparent. The term “percolated network” is conventionally understood to indicate a continuous three dimensional network, in the sense that one of more continuous chains or graphene sheets are present at microscopic distances. In the present invention, a percolated network is formed in a polymer matrix. The polymer is generally a low decomposition temperature polymer which, upon decomposition, results in a high porosity material. Examples of electrodes include charge selective electrodes and catalytic counter electrodes that are particularly suited for use in various solar cells, most preferably in dye-sensitized solar cells.

In the present invention, an electrode (including a charge selective electrode) may be prepared by coating the three dimensional percolated network with at least one semiconductive material, with or without surfaction aids. The semiconductive material(s) can be the form of one or more a thin (<200 nm, preferably <150 nm, more preferably <100 nm, most preferably <50 nm) layers. The layers may comprise the same or different semiconductive materials. Suitable semiconductor materials for use as this coating include, but are not limited to, a metal oxide selected from the group consisting of MₓO_{y} where M is Ti, Zn, Sn, Sr, Ca, In, Nb, Ni, Y, Si, Al, Zr, Mg, Sc, V, La, Sa, Nd, Ga or a combination thereof, and is preferably selected from titanium dioxide, zinc oxide, tin dioxide, indium oxide, strontium titanate, niobium pentoxide, and nickel oxide, silicon dioxide, yttrium oxide, aluminum oxide, zirconium oxide, magnesium oxide, scandium oxide, vanadium oxide, lanthanum oxide, samarium oxide, neodymium oxide, and gallium oxide.

Coating may be done by deposition from a solution, sol-gels, spray pyrolysis, supercritical fluids, vapor deposition, electrodeposition, and any other suitable methods.

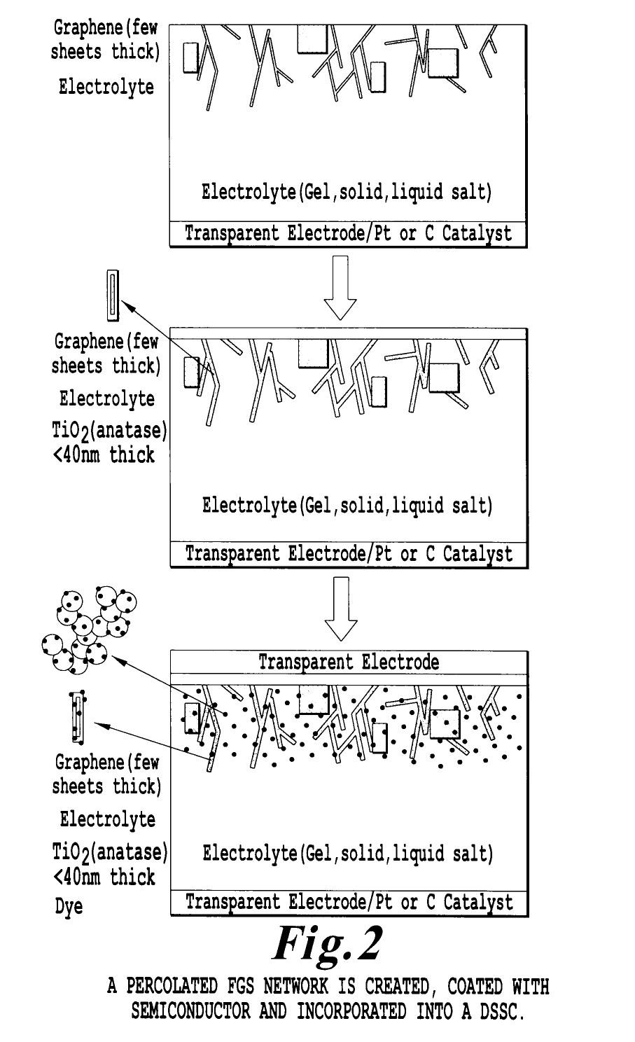

The graphene network provides a high surface area (from 300 m²/g to 2,630 m²/g inclusive, including all values and subranges therebetween) conducting scaffold for the semiconductor layer (see FIG. 2). Both the graphene network and the coating (if used) can be solution processed, greatly reducing the cost of using and scaling up this technology. When used in a preferred embodiment of dye-sensitized solar cells, the present invention effectively reduces the thickness of the semiconductor layer without sacrificing the surface area accessible to dye adsorption. This reduces electron recombination and hence improves the efficiency of the cell.

The present invention can be used in electronics that require high surface area electrodes. The invention can preferably be used in various types of solar cells, most preferably to produce higher efficiency dye-sensitized solar cells. It can also be used to produce higher efficiency bulk-heterogeneous solar cells, and other thin film solar cells.

Several advantages of the present invention are improvements in efficiency due to the system architecture and material properties, though the scalability of the processing is also an asset. Functionalized graphene sheets (also referred to herein as “graphene sheets”) (FGS) can be produced in mass quantities and are commercially available. They have outstanding mechanical and electrical properties, which allow them to carry large currents and reach high temperatures without adverse effects. Additionally, FGS has defects in the hexagonal graphene structure, which can be beneficial for transferring charge between sheets. By creating a percolated network of such microscopic sheets, electric charge can be transported effectively over macroscopic distances. Coating such a network with a semiconductor permits the creation of a charge selective electrode, which can be sensitized by a dye and used in photoelectric devices.

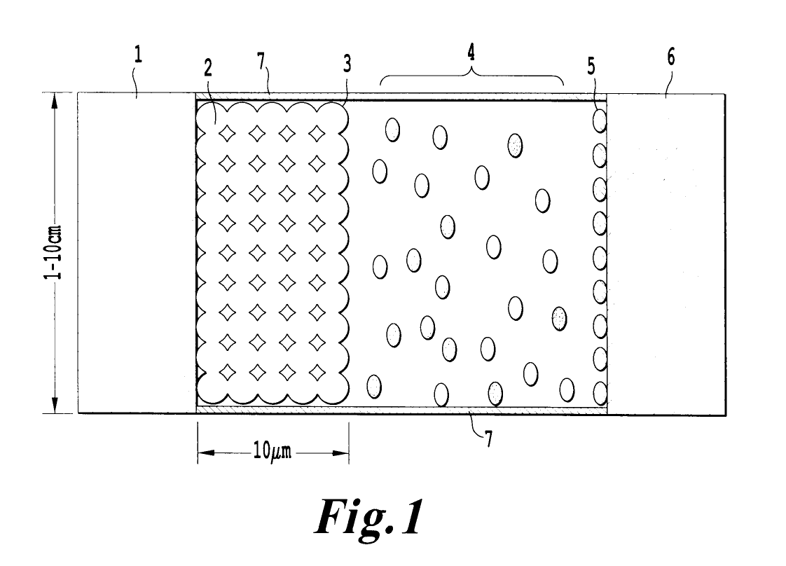

Conventional dye-sensitized solar cells incorporate a planar, layered architecture as exemplified in FIG. 1, in which a porous semiconductor layer 2 is deposited on an electrode surface [Spivack, U.S. Pat. No. 7,145,071, Gratzel, U.S. Pat. No. 4,927,721]. Even with a high surface area, mesoporous semiconductor layer, in order to have appropriate dye loading for photon capture, the conventional semiconductor layer must be on the order of tens of microns. Thus, for electrons to be collected they must diffuse that length without recombination. In the present invention, however, the electrons only have to travel on the order of a hundred nanometers before reaching the electrode. Additionally, in the present invention, there can be a bending of the conduction band which further reduces the likelihood of recombination. These factors lead to greater solar cell efficiency.

A three dimensional, porous electrode for use has been proposed and created by others [see, e.g. Chappel et al, J Phys Chem B, 109, 1643 (2005), and Joanni et al, Scripta Materialia, 57, 277 (2007)]. However, the process to make such a three-dimensional porous electrode involves laser ablation of indium tin oxide (ITO) and semiconductor sputtering, which is not scalable or economical for industrial use. The present invention structure, on the other hand, can be produced using simple, low-cost solution processing such as tape casting or spin coating. This is a low energy process, which does not waste much material, especially compared to vapor deposition techniques.

FGS are suspended in a volatile solvent and mixed vigorously with a low decomposition temperature polymer (such as polyethylene-oxide, poly(methyl methacrylate), poly vinyl acetate, or polyacrylate). This suspension is cast (via tape casting, spin coating, doctor blading) onto a substrate. Any desired substrate can be used, with preference given to glass or plastic coated with various transparent conductors, including, but not limited to, fluorine-doped tin oxide (FTO), indium tin oxide (ITO), carbon nanotubes, or graphene. The polymer is then decomposed (for polyethylene-oxide at temperatures between 200° C.-500° C. in air or nitrogen for one to four hours), leaving a highly porous three-dimensional-network of functionalized graphene sheets. Decomposition under nitrogen converts the polymer into a activated carbon binder.

One preferred form of the percolated network is graphene tapes, which are formed by heating a film comprising graphene sheets. Graphene tapes can be used as electrodes alone (including as catalytic counter electrodes) or when coated with a semiconductor (including as charge-selective electrodes). Solar cells can be made using coated graphene tapes as charge selective electrodes combined with counter electrodes comprising uncoated graphene tapes.

Graphene sheets may be made using any suitable method. For example, they may be obtained from graphite, graphite oxide, expandable graphite, expanded graphite, etc. They may be obtained by the physical exfoliation of graphite, by for example, peeling off sheets graphene sheets. They may be made from inorganic precursors, such as silicon carbide. They may be made by chemical vapor deposition (such as by reacting a methane and hydrogen on a metal surface). They may be may by the reduction of an alcohol, such ethanol, with a metal (such as an alkali metal like sodium) and the subsequent pyrolysis of the alkoxide product (such a method is reported in Nature Nanotechnology (2009), 4, 30-33). They may be made by the exfoliation of graphite in dispersions or exfoliation of graphite oxide in dispersions and the subsequently reducing the exfoliated graphite oxide. Graphene sheets may be made by the exfoliation of expandable graphite, followed by intercalation, and ultrasonication or other means of separating the intercalated sheets (see, for example, Nature Nanotechnology (2008), 3, 538-542). They may be made by the intercalation of graphite and the subsequent exfoliation of the product in suspension, thermally, etc.

Graphene sheets may be made from graphite oxide (also known as graphitic acid or graphene oxide). Graphite may be treated with oxidizing and/or intercalating agents and exfoliated. Graphite may also be treated with intercalating agents and electrochemically oxidized and exfoliated. Graphene sheets may be formed by ultrasonically exfoliating suspensions of graphite and/or graphite oxide in a liquid (which may contain surfactants and/or intercalants). Exfoliated graphite oxide dispersions or suspensions can be subsequently reduced to graphene sheets. Graphene sheets may also be formed by mechanical treatment (such as grinding or milling) to exfoliate graphite or graphite oxide (which would subsequently be reduced to graphene sheets).

Reduction of graphite oxide to graphene may be by means of chemical reduction and may be carried out in graphite oxide in a solid form, in a dispersion, etc. Examples of useful chemical reducing agents include, but are not limited to, hydrazines (such as hydrazine, N,N-dimethylhydrazine, etc.), sodium borohydride, hydroquinone, isocyanates (such as phenyl isocyanate), hydrogen, hydrogen plasma, etc. A dispersion or suspension of exfoliated graphite oxide in a carrier (such as water, organic solvents, or a mixture of solvents) can be made using any suitable method (such as ultrasonication and/or mechanical grinding or milling) and reduced to graphene sheets.

Graphite oxide may be produced by any method known in the art, such as by a process that involves oxidation of graphite using one or more chemical oxidizing agents and, optionally, intercalating agents such as sulfuric acid. Examples of oxidizing agents include nitric acid, sodium and potassium nitrates, perchlorates, hydrogen peroxide, sodium and potassium permanganates, phosphorus pentoxide, bisulfites, etc. Preferred oxidants include KClO₄; HNO₃ and KClO₃; KMnO₄ and/or NaMnO₄; KMnO₄ and NaNO₃; K₂S₂O₈ and P₂O₅ and KMnO₄; KMnO₄ and HNO₃; and HNO₃. Preferred intercalation agents include sulfuric acid. Graphite may also be treated with intercalating agents and electrochemically oxidized. Examples of methods of making graphite oxide include those described by Staudenmaier (Ber. Stsch. Chem. Ges. (1898), 31, 1481) and Hummers (J. Am. Chem. Soc. (1958), 80, 1339).

One example of a method for the preparation of graphene sheets is to oxidize graphite to graphite oxide, which is then thermally exfoliated to form graphene sheets (also known as thermally exfoliated graphite oxide), as described in U.S. Patent Application Publication 2007/0092432, filed Oct. 14, 2005 and published Apr. 26, 2007 (the entire contents of which are hereby incorporated by reference; hereafter “the '432 application”). The thusly formed graphene sheets may display little or no signature corresponding to graphite or graphite oxide in their X-ray diffraction pattern.

The thermal exfoliation may be carried out in a continuous, semi-continuous batch, etc. process.

Heating can be done in a batch process or a continuous process and can be done under a variety of atmospheres, including inert and reducing atmospheres (such as nitrogen, argon, and/or hydrogen atmospheres). Heating times can range from under a few seconds or several hours or more, depending on the temperatures used and the characteristics desired in the final thermally exfoliated graphite oxide. Heating can be done in any appropriate vessel, such as a fused silica, mineral, metal, carbon (such as graphite), ceramic, etc. vessel. Heating may be done using a flash lamp.

During heating, the graphite oxide may be contained in an essentially constant location in single batch reaction vessel, or may be transported through one or more vessels during the reaction in a continuous or batch mode. Heating may be done using any suitable means, including the use of furnaces and infrared heaters.

Examples of temperatures at which the thermal exfoliation of graphite oxide may be carried out are at least about 300° C., at least about 400° C., at least about 450° C., at least about 500° C., at least about 600° C., at least about 700° C., at least about 750° C., at least about 800° C., at least about 850° C., at least about 900° C., at least about 950° C., and at least about 1000° C. Preferred ranges include between about 750 about and 3000° C., between about 850 and 2500° C., between about 950 and about 2500° C., and between about 950 and about 1500° C.

The time of heating can range from less than a second to many minutes. For example, the time of heating can be less than about 0.5 seconds, less than about 1 second, less than about 5 seconds, less than about 10 seconds, less than about 20 seconds, less than about 30 seconds, or less than about 1 min. The time of heating can be at least about 1 minute, at least about 2 minutes, at least about 5 minutes, at least about 15 minutes, at least about 30 minutes, at least about 45 minutes, at least about 60 minutes, at least about 90 minutes, at least about 120 minutes, at least about 150 minutes, at least about 240 minutes, from about 0.01 seconds to about 240 minutes, from about 0.5 seconds to about 240 minutes, from about 1 second to about 240 minutes, from about 1 minute to about 240 minutes, from about 0.01 seconds to about 60 minutes, from about 0.5 seconds to about 60 minutes, from about 1 second to about 60 minutes, from about 1 minute to about 60 minutes, from about 0.01 seconds to about 10 minutes, from about 0.5 seconds to about 10 minutes, from about 1 second to about 10 minutes, from about 1 minute to about 10 minutes, from about 0.01 seconds to about 1 minute, from about 0.5 seconds to about 1 minute, from about 1 second to about 1 minute, no more than about 600 minutes, no more than about 450 minutes, no more than about 300 minutes, no more than about 180 minutes, no more than about 120 minutes, no more than about 90 minutes, no more than about 60 minutes, no more than about 30 minutes, no more than about 15 minutes, no more than about 10 minutes, no more than about 5 minutes, no more than about 1 minute, no more than about 30 seconds, no more than about 10 seconds, or no more than about 1 second. During the course of heating, the temperature may vary.

Examples of the rate of heating include at least about 120° C./min, at least about 200° C./min, at least about 300° C./min, at least about 400° C./min, at least about 600° C./min, at least about 800° C./min, at least about 1000° C./min, at least about 1200° C./min, at least about 1500° C./min, at least about 1800° C./min, and at least about 2000° C./min.

Graphene sheets may be annealed or reduced to graphene sheets having higher carbon to oxygen ratios by heating under reducing atmospheric conditions (e.g., in systems purged with inert gases or hydrogen). Reduction/annealing temperatures are preferably at least about 300° C., or at least about 350° C., or at least about 400° C., or at least about 500° C., or at least about 600° C., or at least about 750° C., or at least about 850° C., or at least about 950° C., or at least about 1000° C. The temperature used may be, for example, between about 750 about and 3000° C., or between about 850 and 2500° C., or between about 950 and about 2500° C.

The time of heating can be for example, at least about 1 second, or at least about 10 second, or at least about 1 minute, or at least about 2 minutes, or at least about 5 minutes. In some embodiments, the heating time will be at least about 15 minutes, or about 30 minutes, or about 45 minutes, or about 60 minutes, or about 90 minutes, or about 120 minutes, or about 150 minutes. During the course of annealing/reduction, the temperature may vary within these ranges.

The heating may be done under a variety of conditions, including in an inert atmosphere (such as argon or nitrogen) or a reducing atmosphere, such as hydrogen (including hydrogen diluted in an inert gas such as argon or nitrogen), or under vacuum. The heating may be done in any appropriate vessel, such as a fused silica or a mineral or ceramic vessel or a metal vessel. The materials being heated including any starting materials and any products or intermediates) may be contained in an essentially constant location in single batch reaction vessel, or may be transported through one or more vessels during the reaction in a continuous or batch reaction. Heating may be done using any suitable means, including the use of furnaces and infrared heaters.

The graphene sheets preferably have a surface area of at least about 100 m²/g to, or of at least about 200 m²/g, or of at least about 300 m²/g, or of least about 350 m²/g, or of least about 400 m²/g, or of least about 500 m²/g, or of least about 600 m²/g, or of least about 700 m²/g, or of least about 800 m²/g, or of least about 900 m²/g, or of least about 700 m²/g. The surface area may be about 400 to about 1100 m²/g. The theoretical maximum surface area can be calculated to be 2630 m²/g. The surface area includes all values and subvalues therebetween, especially including 400, 500, 600, 700, 800, 900, 1000, 1100, 1200, 1300, 1400, 1500, 1600, 1700, 1800, 1900, 2000, 2100, 2200, 2300, 2400, 2500, and 2630 m²/g.

The graphene sheets can have number average aspect ratios of about 100 to about 100,000, or of about 100 to about 50,000, or of about 100 to about 25,000, or of about 100 to about 10,000 (where “aspect ratio” is defined as the ratio of the longest dimension of the sheet to the shortest).

Surface area can be measured using either the nitrogen adsorption/BET method at 77 K or a methylene blue (MB) dye method in liquid solution. The BET method is preferred. The dye method is carried out as follows: A known amount of graphene sheets is added to a flask. At least 1.5 g of MB are then added to the flask per gram of graphene sheets. Ethanol is added to the flask and the mixture is ultrasonicated for about fifteen minutes. The ethanol is then evaporated and a known quantity of water is added to the flask to re-dissolve the free MB. The undissolved material is allowed to settle, preferably by centrifuging the sample. The concentration of MB in solution is determined using a UV-vis spectrophotometer by measuring the absorption at λₘₐₓ=298 nm relative to that of standard concentrations.

The difference between the amount of MB that was initially added and the amount present in solution as determined by UV-vis spectrophotometry is assumed to be the amount of MB that has been adsorbed onto the surface of the graphene sheets. The surface area of the graphene sheets are then calculated using a value of 2.54 m² of surface covered per one mg of MB adsorbed.

The graphene sheets may have a bulk density of from about 0.1 to at least about 200 kg/m³. The bulk density includes all values and subvalues therebetween, especially including 0.5, 1, 5, 10, 15, 20, 25, 30, 35, 50, 75, 100, 125, 150, and 175 kg/m³.

The graphene sheets may be functionalized with, for example, oxygen-containing functional groups (including, for example, hydroxyl, carboxyl, and epoxy groups) and typically have an overall carbon to oxygen molar ratio (C/O ratio), as determined by elemental analysis of at least about 1:1, or more preferably, at least about 3:2. Examples of carbon to oxygen ratios include about 3:2 to about 85:15; about 3:2 to about 20:1; about 3:2 to about 30:1; about 3:2 to about 40:1; about 3:2 to about 60:1; about 3:2 to about 80:1; about 3:2 to about 100:1; about 3:2 to about 200:1; about 3:2 to about 500:1; about 3:2 to about 1000:1; about 3:2 to greater than 1000:1; about 10:1 to about 30:1; about 80:1 to about 100:1; about 20:1 to about 100:1; about 20:1 to about 500:1; about 20:1 to about 1000:1; about 50:1 to about 300:1; about 50:1 to about 500:1; and about 50:1 to about 1000:1. In some embodiments, the carbon to oxygen ratio is at least about 2:1, or at least about 5:1, or at least about 10:1, or at least about 20:1, or at least about 35:1, or at least about 50:1, or at least about 75:1, or at least about 100:1, or at least about 200:1, or at least about 300:1, or at least about 400:1, or at least 500:1, or at least about 750:1, or at least about 1000:1; or at least about 1500:1, or at least about 2000:1. The carbon to oxygen ratio also includes all values and subvalues between these ranges.

The graphene sheets may contain atomic scale kinks. These kinks may be caused by the presence of lattice defects in, or by chemical functionalization of the two-dimensional hexagonal lattice structure of the graphite basal plane.

The films may be prepared by a solution processing method. Suspensions comprising graphene sheets, a solvent, at least one polymer binder, and optionally at least one surfactant may be applied to a substrate using any suitable process, including a doctor blade method, casting, spin casting, spin coating, dip coating, printing, spray coating, electrospraying, etc. The solvent may then be removed by drying or evaporation, by polymerizing or curing (such as by light, heat, etc.), and/or any other suitable method. The film is heated to decompose the binder (and surfactant, if used) and form the tape. After decomposition, preferably no more than about 60 percent, or no more than about 50 percent, or no more than about 40 percent, or no more than about 25 percent, or no more than about 20 percent, or no more than about 15 percent, or no more than about 10 percent, or no more than about 5 percent of the original binder and surfactant (if present) mass remains in the tapes. The amount of binder (and surfactant if present) remaining can be determined by measuring loss in mass of the tape relative to that of the precursor film.

The graphene sheets may be cross-linked by, for example covalently bound tethers, etc., to each other prior to being combined with the binder (or binder precursors), or they may be held together by covalent bound tethers without the need for an extra binder. They may also be cross-linked after they have been combined, during solvent removal, and/or during heating.

In some embodiments, the graphene sheets may comprise about 5 to about 70 weight percent, or about 5 to about 60 weight percent, or about 5 to about 50 weight percent, or about 10 to about 45 weight percent of the total amount of graphene sheets, binder, and surfactant (if used).

Examples of substrates include glass, including glass that has been surface treated (such as with a silane) to facilitate removal of the films or tapes, silicon, metals (such as for electrode applications), polymers, solid or gel electrolytes, etc. Examples of solvents include water (including water at various pHs), alcohols (such as methanol, ethanol, propanol, etc.), chlorinated solvents (such as methylene chloride, chloroform, carbon tetrachloride, etc.), tetrahydrofuran, dimethylformamide, N-methylpyrrolidone, gamma-butyrolactone, etc.

The suspensions may further comprise surfactants such as poly(ethylene oxide)s, poly(propylene oxide)s, ethylene oxide/propylene oxide copolymers (including block copolymers), gum arabic, poly(vinyl alcohol), ionic surfactants, sulfates (sulfates (such as alkyl sulfates (including ammonium lauryl sulfate, sodium lauryl sulfate (SDS) and alkyl ether sulfates (such as sodium laureth sulfate)), sulfonates, phosphates (including alkyl aryl ether phosphates and alkyl ether phosphates), carboxylates, cationic amines, quaternary ammonium cations, etc.

Examples of polymeric binders include polysiloxanes (such as poly(dimethylsiloxane), dimethylsiloxane/vinylmethylsiloxane copolymers, vinyldimethylsiloxane terminated poly(dimethylsiloxane), etc.), polyethers and glycols such as poly(ethylene oxide)s (also known as poly(ethylene glycol)s, poly(propylene oxide)s (also known as poly(propylene glycol)s, and ethylene oxide/propylene oxide copolymers (including block copolymers), cellulosic resins (such as ethyl cellulose, ethyl hydroxyethyl cellulose, carboxymethyl cellulose, cellulose acetate, cellulose acetate propionates, and cellulose acetate butyrates), and poly(vinyl butyral), polyvinyl alcohol and its derivatives, poly(vinyl acetate), ethylene/vinyl acetate polymers, acrylic polymers and copolymers (such as methyl methacrylate polymers, methacrylate copolymers, polymers derived from one or more acrylates, methacrylates, ethyl acrylates, ethyl methacrylates, butyl acrylates, butyl methacrylates and the like), styrene/acrylic copolymers, styrene/maleic anhydride copolymers, isobutylene/maleic anhydride copolymers, vinyl acetate/ethylene copolymers, ethylene/acrylic acid copolymers, polyolefins, polystyrenes, olefin and styrene copolymers, epoxy resins, acrylic latex polymers, rubbers, natural rubbers, butyl rubbers, nitrile rubbers, polyester acrylate oligomers and polymers, polyester diol diacrylate polymers, UV-curable resins, polyamides, etc.

Suspensions containing polymerizable monomers and/or oligomers may also be used, wherein at least a portion of the polymer binder is formed by polymerizing the monomers and/or oligomers in the presence of the graphene sheets. In such cases the monomers and/or oligomers can serve as some or all of the solvent.

Suitable decomposition heating temperatures are at least about 150° C. The film may also be heated at at least about 200° C., at at least about 300° C., at at least about 400° C., at at least about 500° C., at least about 750° C., at at least about 1000° C., at at least about 1100° C., at at least about 1200° C., at at least about 1300° C., at at least about 1500° C., at at least about 2000° C., at at least about 2200° C., between about 300 and 750° C., between about 300 and 1000° C., between about 750 and 1500° C., and between about 950 and about 2000° C. Higher heating temperatures often lead to tapes with increased electrical conductivity and decreased mechanical properties.

Heating may be done in any suitable vessel (including furnaces) and preferably under a non-oxidizing atmosphere such as nitrogen or argon.

The tapes may be further annealed by heating after the binder is decomposed. At temperatures above about 1500° C., healing of certain graphene lattice defects may occur.

The films may be peeled off the substrate prior to the binder decomposition step or after the tapes have been formed.

In some embodiments, the films and tapes may have a thickness of about 0.1 micron to about 1 micron, or about 0.1 microns to about 1 mm, or about 1 micron to about 1 mm, or about 1 micron to about 500 microns, or about 5 microns to about 500 microns, or about 10 microns to about 100 microns, or about 20 microns to about 75 microns, or about 30 microns to about 60 microns. Thicker films may be formed by coating one or more additional layers over an already formed film or tape.

The tapes are preferably free-standing, self-supporting materials that may be handled unattached to a substrate or other backing materials. Free-standing tapes may be attached to other materials, including surface, substrates, backing materials, etc. when used in certain applications.

There are no particular limitations to the length and width of the tapes. They may be cut or otherwise formed into any desired shape. They may be sufficiently flexible to be bent at an angle of at least about 90° without breaking. In some cases they may be sufficiently flexible to bent at an angle of at least about 150° without breaking. The radius of curvature may be less than about 1 cm.

The tapes can have carbon to oxygen ratios in the same ranges as those described above for the graphene sheets.

The percolated network (including tapes) can have a density of about 0.05 to about 1 g/cm³, or about 0.1 to about 0.6 g/cm³. The percolated network (including tapes) can have a surface area of at least about 30 m²/g, or at least about 50 m²/g, or at least about 100 m²/g, or at least about 150 m²/g, or at least about 200 m²/g, or at least about 300 m²/g, or at least about 400 m²/g, or at least about 500 m²/g, or at least about 700 m²/g. Surface area can be measured as described above using either the nitrogen adsorption/BET method at 77 K or a methylene blue (MB) dye method in liquid solution.

The percolated network (including tapes) can be electrically conductive. In some embodiments of the invention, the electrodes have conductivities of at least about 0.001 S/m, of at least about 0.01 S/m, of at least about 0.1 S/m, of at least about 1 S/m, of at least about 10 S/m, of at least about 100 S/m, or at least about 150 S/m, or at least about 200 S/m, or at least about 300 S/m, or at least about 500 S/m, or at least about 750 S/m, or at least about 1000 S/m, or at least about 10,000 S/m, or at least about 20,000 S/m, or at least about 30,000 S/m, or at least about 40,000 S/m, or at least about 50,000 S/m, or at least about 60,000 S/m, or at least about 75,000 S/m, or at least about 10⁵ S/m, or at least about 10⁶ S/m.

In one embodiment, networks of FGS can be soaked in a low temperature (<100° C.) titanium chloride solution with or without surfactant templation aides, effectively coating it with TiO₂. Other conventional coating procedures using sol-gels, spray pyrolysis, supercritical fluids, vapor deposition, or electrodeposition could also be used.

The resulting high surface area layer can then be used in a variety of end products. To use a semiconductor-coated FGS network in the completion of a solar cell, such as a dye-sensitized solar cell, the layer must be photosensitized and then incorporated into the standard dye-sensitized solar cell architecture. One is method of achieving this end is to soak the semiconductor-coated FGS network in a photosensitive dye. Suitable dyes include any conventional dye used in dye-sensitized solar cell production, including, but not limited to, ruthenium polypyridyl complexes such as Ru(4,4′-dicarboxy-2,2′-bipyridyl)₂(SCN)₂, and organic dyes such as coumarin, hemicyanine, and indoline.

A sealing spacer (preferably 25-100 μm SURLYN or BYNEL) is melted onto a catalytic counter electrode (preferably platinum coated FTO, uncoated FGS scaffolds (including graphene tapes), and/or uncoated FGS scaffolds (including graphene tapes) used with FTO). The electrode-FGS-semiconductor plate (such as FTO-FGS-TiO₂) is then pressed onto the sealant and cooled.

An electrolyte (preferably I⁻/I₃⁻ based) is added through holes in the catalyst-electrode plate (Pt-FTO) and the holes are subsequently sealed (with, for example, SURLYN or BYNEL). The architecture is presented in FIG. 2. Other electrolyte systems include redox couples (such as Co^{11/111}(dbbip)₂](ClO4)₂ (e.g. Co¹¹ and Co¹¹¹ complexes), (SeCn)⁻₃/SeCN⁻, all with or without gelators), solid-state hole conductor materials (such as spiro-OMeTAD (2,2′,7,7′-tetrakis(N,N-di-p-methoxypheny-amine)-9,9′-spirobi-fluorene), ionic liquids, or molten salts.

In some embodiments, the solar cells may have a power conversion efficiency of at least about 3%, or at least about 4%, or at least about 5%, or at least about 6%, or at least about 10%.

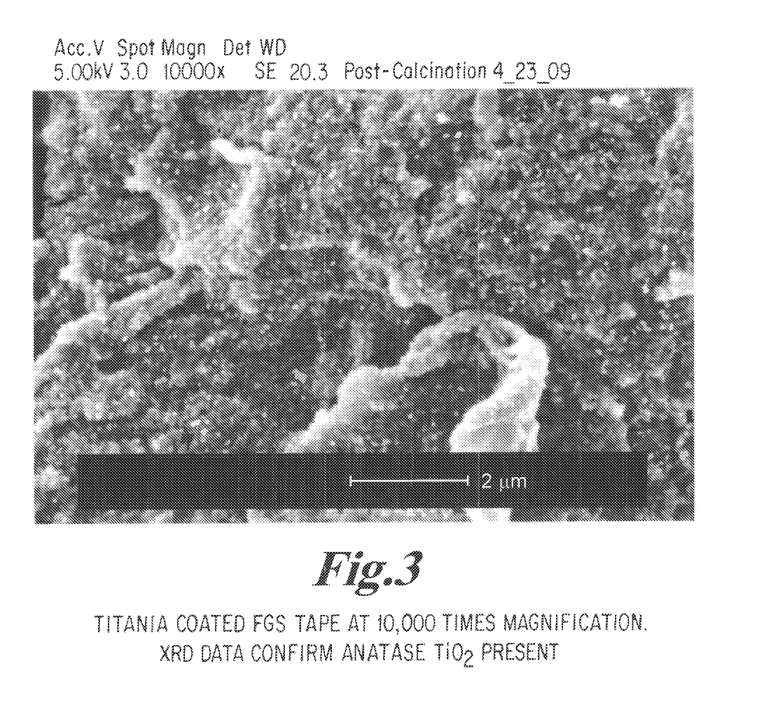

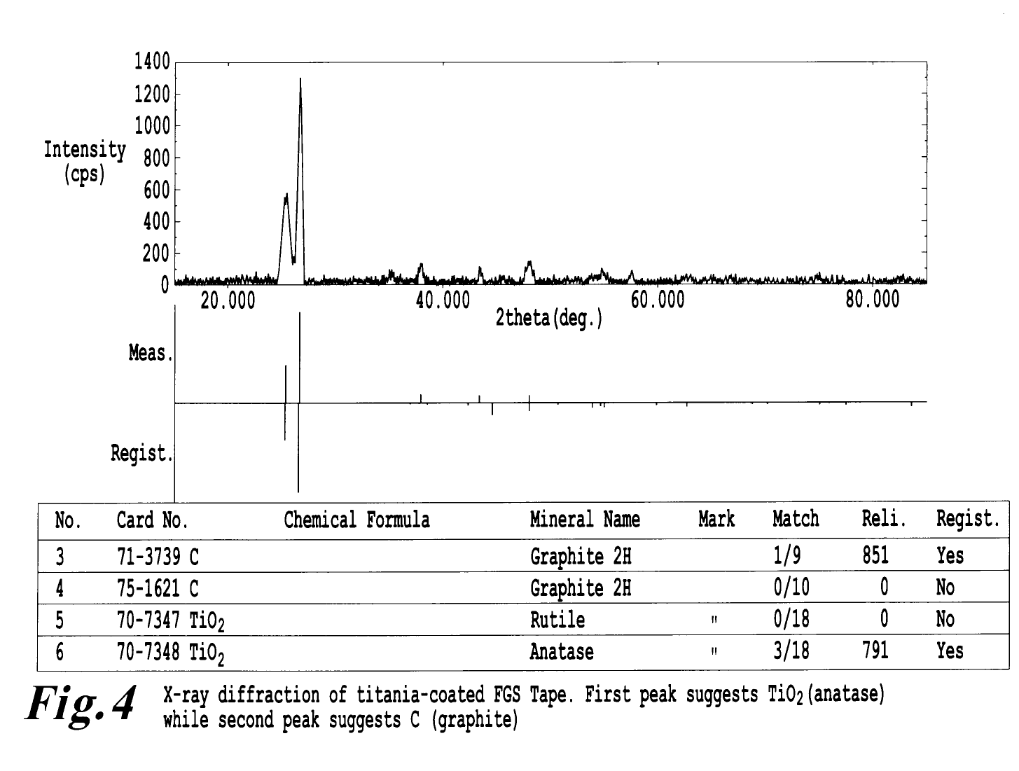

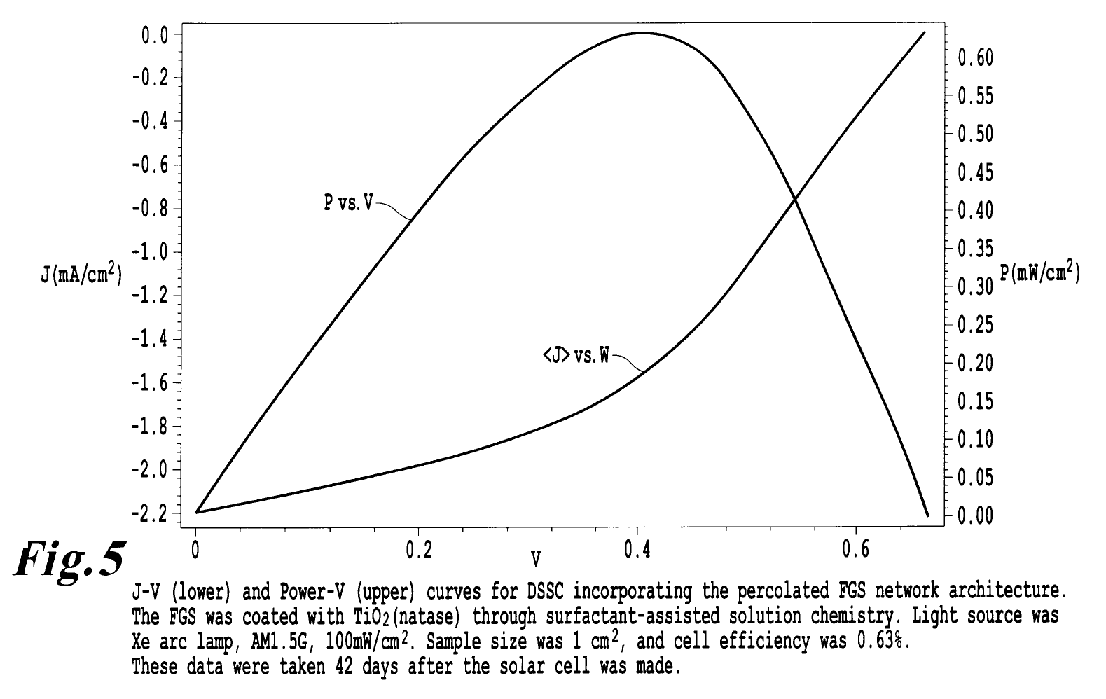

FGS tapes have been created and coated with TiO₂. These tapes are seen in the SEM images in FIG. 3 and their X-ray diffraction spectra are seen in FIG. 4. An exemplary dye-sensitized solar cell has been prepared in accordance with the present invention. The resulting dye-sensitized solar cell had a structure of FTO-FGS-TiO₂-dye-electrolyte-Pt-FTO. The J-V and Power-V curves of the dye-sensitized solar cell are shown in FIG. 5.

The present invention can be incorporated in roll to roll processing as a coating to a transparent, conducting substrate. The invention thus reduces the length required for electron transport, reduces back recombination to the electrolyte, and improves cell efficiency.

### EXAMPLES

### Example 1

An FGS scaffold precursor solution was prepared by the following: 170 mg FGS in 5 ml water was mixed with 170 mg sodium dodecyl sulfate (SDS) in 5 ml water. This suspension was sonicated and added to a 20 mL of polyethylene oxide (PEO) solution containing 600 mg of PEO (MW=60,000 Da) in 10 mL ethanol and 10 mL water. 500 uL of FGS scaffold precursor solution was spin coated at 1500 rpm onto a piece of FTO coated glass. This glass, with FGS precursor solution, was then heated to 400° C. for 1 hour to decompose the surfactant and polymer and introduce greater porosity. The FGS scaffold on FTO glass was then immersed in a TiO₂ precursor solution at 90° C. for 16 hours. The TiO₂ precursor solution consisted of 0.6 mL of 0.5 M SDS, 3.2 mL TiCl₃ (12 wt %), 5 mL Na₂SO₄ (0.6 M), 833 uL H₂O₂ (3 wt %) and 70.36 mL water. After the reaction, the electrode was removed and washed in water and ethanol, before being dried overnight at 70° C. under vacuum. The electrode was heated to 400° C. for 2 hours to sinter the TiO₂ and decompose the SDS. To complete the solar cell, a counter electrode was made by depositing platinum particles on FTO from an ethanol suspension, and a 50 um spacer of scotch tape was applied to the edge of the glass. The two electrodes were sandwiched together and an electrolyte consisting of acetonitrile, iodide, triiodide, and 4-tert-butylpyridine was introduced via capillary action. The photovoltaic performance of the cell was then measured by a potentiostat under an AM1.5G solar simulator.

### Examples 2-4 and Comparative Example 1

### Preparation of Counter Electrodes

For electrodes used in electrochemical impedance spectroscopy (EIS) and DSSCs, graphene counter electrodes were prepared on FTO (TEC8 Hartford Glass). A Graphene-(F-127) suspension (1.66 wt % graphene, 1.66 wt % F-127 in water) was mixed in a PEO solution (0.6 g in 10 mL water, 10 mL ethanol) in a 1:4 graphene:PEO weight ratio and stirred overnight. The resulting suspension was spin coated onto clean FTO (fluorine-doped tin oxide) substrates at speeds of 1000, 2000, and 4000 rpm (corresponding to those used in Examples 2, 3, and 4, respectively) for 4 min. The resulting film was dried at room temperature and then the surfactants were thermally decomposed in an ashing furnace at 350° C. in air for 2 h. Thermally treated chloroplatinic acid electrodes, (used for Comparative Example 4), were prepared as described in the Journal of The Electrochemical Society 1997, 144, (3), 876-884. Briefly, 2 μL of 5 mM chloroplatinic acid in isopropanol were drop cast on an FTO electrode with a 0.39 cm² mask. The sample was then heated to 380° C. for 20 min before use.

### Preparation of DSSCs

DSSCs were constructed as described previously in the literature (Journal of the American Chemical Society 1993, 115, (14), 6382-6390) In brief, 2 g of P25 titania nanoparticles (Evanonik) were suspended with 66 μL of acetylacetone and 3.333 mL deionized water. Titania films, four layers thick, were cast on TiCl₄ treated FTO glass using a scotch tape mask and a glass rod via the doctor blade technique. These films were then heated to 485° C. for 30 min in air before being placed in a 0.2M TiCl₄ solution for 12 h and heated to 450° C. for 30 min. The resulting electrode was immersed in a 0.3 mM N3 dye-ethanol (Acros) solution for 20 h to form the sensitized photocathode. Platinum and graphene counter electrodes were formed as described above. A 25 μm Surlyn film (Solaronix) was used to separate the photocathode and counter electrode and seal the cell after electrolyte (Iodolyte AN-50 from Solaronix) was added. Cells were tested immediately after fabrication.

Measurements

Current-voltage characteristics of DSSCs were taken under AM1.5G light, simulated at 100 mW/cm² with a 16S solar simulator (SolarLight) using a potentiostat (Biologic SP-150) to apply various loads. Data values presented are the average of 2 to 6 identically prepared samples. The results are given in Table 1, where V_{oc} refers to the open circuit voltage. J_{sc} refers to the short circuit current density. η refers to cell efficiency (the cell's maximum power output divided by the input power, per area). FF refers to the fill factor, which is the ratio of the maximum power obtainable in the device to the theoretical maximum power [FF=(J*×V*)/(J_{sc}×V_{oc}), where J* and V* are the current density and voltage, respectively, at the cell's maximum power output].

EIS was performed on the electrodes using a Biologic SP-150 potentiostat. EIS was performed using a sandwich cell configuration with symmetric tape electrodes (Example 2) and symmetric platinum coated FTO electrodes (Comparative Example 1) in an acetonitrile electrolyte containing 0.5 M LiI and 0.05 M I₂. A 25 μm thick Surlyn® film was used to separate the tape electrodes and seal the cells. EIS measurements were taken from 0 V to 0.8 V, the magnitude of the alternating signal was 10 mV, and the frequency range was 1 Hz to 400 kHz. ZFit (Biologic), with the appropriate equivalent circuit, in which the mid-frequency hump from about 2500 to about 25 Hz represents the charge transfer resistance (R_{CT}), was used to analyze the impendence spectra and determine R_{CT} of the electrodes. The results are given in Table 1.

TABLE 1

| | Electrode | | J_{sc} (mA | | |
|---|---|---|---|---|---|
| | material | V_{oc} (V) | cm⁻²) | FF | η (%) |
| Example 2 | Graphene | 0.64 | 13.16 | 0.60 | 4.99 |
| | tape | | | | |
| Comparative | Platinum | 0.64 | 13.03 | 0.67 | 5.48 |
| Example 1 | on FTO | | | | |

TABLE 2

| | Coating spin | R_{CT} value (Ohm cm²) | | |
|---|---|---|---|---|
| | rate (rpm) | 0 V Bias | 0.3 V Bias | 0.5 V Bias |
| Example 2 | 1000 | 9.37 | 1.82 | 1.19 |
| Example 3 | 2000 | 14.49 | 1.96 | 1.18 |
| Example 4 | 3000 | 19.70 | 2.77 | 1.45 |
| Comparative | not applicable | 0.82 | 0.8 | 0.79 |
| Example 1 | | | | |

Obviously, numerous modifications and variations of the present invention are possible in light of the above teachings. It is therefore to be understood that within the scope of the appended claims, the invention may be practiced otherwise than as specifically described herein.

1. A high surface area scaffold to be used for a solar cell, comprising:
a three-dimensional percolated network of functionalized graphene sheets.

2. The high surface area scaffold of claim 1, wherein the percolated functionalized graphene sheets have surface areas of from 300 m²/g to 2630 m²/g.

3. The high surface area scaffold of claim 1, wherein the percolated network of functionalized graphene sheets is in the form of graphene tapes.

4. The high surface area scaffold of claim 1, wherein the functionalized graphene sheets comprise a network of single graphene sheets.

5. The high surface area scaffold of claim 1, wherein the functionalized graphene sheets comprise stacks from 2 to 10 graphene sheets.

6. The high surface area scaffold of claim 1, wherein the functionalized graphene sheets comprise stacks from more than 10 graphene sheets.

7. The high surface area scaffold of claim 1, wherein the functionalized graphene sheets comprise a combination of single sheet graphene and stacks of 2 or more graphene sheets.

8. The high surface area scaffold of claim 1, wherein the three-dimensional network of functionalized graphene sheets has a thickness of from 0.01 to 100 μm.

9. The high surface area scaffold of claim 1, wherein the three-dimensional percolated network of functionalized graphene sheets is optically semi-transparent.

10. A high surface area electrode in which the electrode comprises the scaffold of claim 1, coated with at least one semiconductive material.

11. The high surface area coated electrode of claim 10, wherein the scaffold is a graphene tape.

12. The high surface area electrode of claim 10, wherein the semiconductive material is a metal oxide selected from the group consisting of MₓO_{y} where M is Ti, Zn, Sn, Sr, Ca, In, Nb, Ni, Y, Si, Al, Zr, Mg, Sc, V, La, Sa, Nd, Ga or a combination thereof.

13. The high surface area conductive scaffold of claim 10, wherein the semiconductive material has a thickness of <50 nm.

14. The high surface area conductive scaffold of claim 10, wherein the semiconductive material has a thickness between 50 nm and 150 nm.

15. The high surface area conductive scaffold of claim 10, wherein the semiconductive material has a thickness greater than 150 nm.

16. A method of coating the conducting scaffold of claim 1, wherein the scaffold is coated with a semiconductor.

17. The method of claim 16, wherein the a metal oxide precursor nucleates on the scaffold from a solution.

18. The method of claim 17, in which the solution contains titanium chloride (TiCl₃ or TiCl₄) as the metal oxide precursor.

19. The method of claim 17, in which the solution contains hydrogen peroxide.

20. The method of claim 17, in which the solution is heated to between 40° C. and 100° C.

21. The method of claim 17, in which in which the solution contains a surfactant to template metal oxides on to the scaffold.

22. The method claim 17, in which a metal oxide precursor is electrodeposited on the scaffold.

23. The method of claim 16, in which a metal oxide precursor nucleates on the scaffold from chemical vapor infiltration.

24. The method of claim 16, in which a metal oxide precursor nucleates on the scaffold from a supercritical carrier fluid.

25. The method of claim 24, in which the supercritical fluid is carbon dioxide.

26. The method of claim 24, in which the metal oxide precursor is titanium chloride (TiCl₃ or TiCl₄).

27. The method of claim 16, in which a metal oxide precursor forms on the scaffold from a sol-gel technique.

28. The method of claim 16, in which a metal oxide precursor is deposited on the scaffold from spray pyrolysis.

29. The scaffold of claim 1 in the form of an electrode.

30. The semiconductor coated scaffold of claim 10 in the form of a charge selective electrode.

31. An electronic device having at least one electrode selected from the group consisting of the scaffold of claim 29 and the coated scaffold of claim 30.

32. A solar cell, having at least one electrode selected from the group consisting of the scaffold of claim 29 and the coated scaffold of claim 30.

33. The solar cell of claim 27, wherein the solar cell is a dye-sensitized solar cell.
